(19) United States
(12) Patent Application Publication
(10) Pub. No.: US 2026/0353616 A1
(43) Pub. Date: Nov. 5, 2026

(54) ASSEMBLY WITH CONVERTER FOR CONVERTING ELECTRICAL CURRENT AND VOLTAGE TYPES AND METHOD OF MANUFACTURING AN ASSEMBLY WITH CONVERTER

(71) Applicant: MAGNA Powertrain GmbH & Co KG, Lannach (AT)

(72) Inventors: Patrick Lamplmayr, St. Georgen (AT); Josef Schadauer, Wolfsbach (AT)

(21) Appl. No.: 19/119,855

(22) PCT Filed: Oct. 4, 2023
(86) PCT No.: PCT/EP2023/077494

§ 371 Date: Apr. 10, 2025

(30) Foreign Application Priority Data
Oct. 11, 2022 (DE) 10 2022 210 716.0

(51) Int. Cl. H05K 7/20; H02M 7/00

(52) U.S. Cl. CPC H05K 7/209; H02M 7/003; H05K 7/2049

(57) ABSTRACT

An assembly with a converter for converting electric current types and voltage types includes at least one power module and at least one intermediate circuit device that is connected to the power module in an electrically conductive manner. The intermediate circuit device is connected such that the converter converts one electric current or voltage type into another, and includes at least one cooling channel. A respective first cooling side of the power module and of the cooling channel is fixed together and operatively connected together in a thermal manner such that exhaust heat is transferred from the power module to the coolant flowing through the cooling channel via the cooling sides of the power module and of the cooling channel.

### CROSS REFERENCE TO RELATED APPLICATIONS

This application is a National Stage of International Application No. PCT/EP 2023/077494, filed Oct. 4, 2023, which claims priority to DE 10 2022 210 716.0, filed Oct. 11, 2022. The entire disclosures of each of the above applications are incorporated herein by reference.

### FIELD

The present disclosure relates to an assembly with converter for converting electric current types and voltage types, having a power module and having a DC link device electrically conductively connected to the power module, wherein the DC link device can be electrically conductively connected to an energy supply device so that the converter can convert one type of electric current or voltage into another, and having a cooling channel, wherein in each case a first cooling side of the power module and the cooling channel are fixed on one another and are thermally operatively connected to one another, so that waste heat can pass from the power module via the cooling sides of the power module and the cooling channel into the coolant flowing through the cooling channel.

The present disclosure also relates to a method for producing an assembly with a converter, wherein a power module is fixed using a first cooling side on a first cooling side of a cooling channel, wherein the cooling channel is formed in at least two parts and can have a coolant flow through it so that waste heat can pass from the power module via the cooling sides of the power module and the cooling channel into a coolant flowing through the cooling channel, and wherein a DC link device is electrically conductively connected to the power module so that the converter can convert one type of electric current or voltage into another.

### BACKGROUND

This section provides information related to the present disclosure which is not necessarily prior art.

Converters are known from practice, where an arbitrary type of current or voltage can be converted into another type of current or voltage. The power modules are decisive in this case, wherein the converter has to include one. The one power module typically includes multiple semiconductors, which are electrically conductively connected in a B4 or B6 bridge circuit; wherein it is also possible that one power module only includes a quarter or half bridge circuit and the converter accordingly has to include multiple power modules.

Waste heat caused by the switching losses of the semiconductors accumulates in the power module, which has to be discharged from the power module so that the power module or the semiconductors are not destroyed. For this purpose, the power module is thermally operatively connected to the cooling channel through which a coolant flows, so that the power module can emit the waste heat into the coolant.

A power electronics assembly is known from document U.S. Pat. No. 11,246,244 B2, wherein the power electronics assembly includes a heatsink, at least two half bridge modules, which are installed on one side of the heatsink, a printed circuit board installed on the half bridge modules, and at least one capacitor installed on the printed circuit board. Each of the half bridge modules includes a housing, which has a cold side which is installed on the heatsink. The housing includes a connection side here, from which numerous connection pins for each direct-current connection in the half bridge module protrude, which are connected to the printed circuit board, wherein conductors in the printed circuit board are designed so that they connect the half bridge modules in parallel and connect them to the at least one capacitor in order to form a DC link. The above approach according to the document and the approaches known from the prior art have the disadvantage that not only the power module generates waste heat, but also other components of the converter can generate waste heat which also has to be discharged before they are damaged.

The previous inverter embodiments have the disadvantage of the relatively high costs of the full bridge, the somewhat complex coolant guidance in the inverter housing, the required processing of the housing in the sealing area to the full bridge, and the inflexibility with respect to positioning of the power semiconductor.

A further disadvantage is the dependence of the inverter housing on the power semiconductors used, which has the result that the respective assemblies only fulfill their purpose and can also be verified in the overall structure. A pressure test of the cooling system can thus only take place in the overall structure with the conventional design.

Different customer-specific installation situations therefore require complex costly checks of all assemblies/parts, even if they only change slightly from one another.

EP 2 797 112 A1 discloses a semiconductor module which is installed in a motor control unit of an electric vehicle. A transistor and a diode, which form a switching element of an inverter, and a smoothing capacitor are integrated therein. The semiconductor module primarily consists of a plurality of cooling plates, a plurality of flat plate semiconductor housings, and a plurality of device housings, each of which contains a capacitor. Coolant flows in the interior of the cooling plates, so that the coolant withdraws heat from the semiconductor packets and the device packets in order to cool these packets.

US 2014/0 003 111 A1 discloses an electrical power converter which has a semiconductor module in which a switching element is located, cooling pipes which come into contact with heat-emitting surfaces of the semiconductor module and cool the semiconductor module, and a capacitor module, which is formed by sealing a capacitor element located therein using a potting material. A stacked unit results due to the stacking of the semiconductor module and the cooling pipes. The stacked unit is clamped between the capacitor module, which is arranged at a first end side in the stack direction of the stacked unit, and a pressing element, which is screwed onto a second end side in the stack direction of the stacked unit. The first end of the stacked unit is in contact with a potting surface, which is a surface of the potting material in the capacitor module.

US 2001/0 033 477 A1 is a coolant-cooled semiconductor device, which achieves outstanding heat emission capability and at the same time has a simple structure. A plurality of semiconductor modules is arranged so that the main surface directions of these semiconductor modules are arranged parallel to one another in an interval along their thickness direction. These semiconductor modules are enclosed by a coolant pipe, which includes folded sections having fastening elements. As a result, both surfaces of the semiconductor module can be cooled by a single coolant pipe using a uniform clamping force.

EP 3 188 232 A1 discloses a power semiconductor module having a partition wall element, which includes multiple openings, a semiconductor, and a film capacitor, multiple coolers housed in the openings, and a seal material sealing in the openings on the one side, wherein the semiconductor and the film capacitor are housed alternately in the openings on the one side, both the semiconductor and the film capacitor are housed individually between two of the multiple coolers in order to permit a dissipation of heat, and the seal material embeds the semiconductor, the film capacitor, and the multiple busbars.

US 2016/0 073 556 A1 comprises an electrical power converter having a housing having a receptacle space formed therein, a first circuit section, which is a part of an electrical power converter circuit and is arranged on an upper space of the receptacle space, a second circuit section, which is a further part of the electrical power converter circuit and is arranged on a lower side of the receptacle space, a first flow passage, which is designed so that a fluid passes through while it exchanges heat with the first circuit section, a second flow passage, which is designed so that a fluid passes through while it exchanges heat with the second circuit section, and a plate-like connecting plate, which is attached in a state in which one main surface thereof is arranged along a side wall of the housing. Connecting channels are formed in the connecting plate, which establishes a connection between the first flow channel and the second flow channel.

DE 10 2016 121 914 A1 includes an electrical converter having a semiconductor module having an installed switching element, an electronic component which is electrically connected to the semiconductor module, a plurality of cooling pipes for cooling the semiconductor module and the electronic component in that they are clamped from both sides, a housing for receiving the semiconductor module, the electronic component, and the cooling pipes, a main pressure element for pressing a semiconductor stack section, which is formed by stacking the semiconductor module and the cooling pipes in a stack direction, and a secondary pressure element for stacking a component stack section which is formed by stacking the electronic component and the cooling pipes in the stack direction.

US 2014/0 001 630 A1 discloses a pressure unit, including a spring element which is brought into a coil shape by winding a wire rod and has a periodically changing pitch angle, and a housing element, on which end sections of the spring element are fastened, and the pressure unit places a stacked semiconductor unit under pressure, which is obtained by alternately stacking a semiconductor element module and a cooling pipe, which comes into contact with the semiconductor element module and cools the semiconductor element module.

### SUMMARY

This section provides a general summary of the disclosure, and is not a comprehensive disclosure of its full scope or all of its features.

It is therefore an object of the present disclosure to provide an independent assembly with converter and cooler and a method for producing an assembly, by which the waste heat of the components producing the greatest waste heat can be effectively discharged and which can be placed easily on further components to be cooled.

The object is achieved according to the present disclosure by an assembly with converter, where a cooling side of the DC link device is fixed on a second cooling side of the cooling channel opposite to the power module, so that waste heat from the DC link device can pass via the second cooling side of the cooling channel into the coolant flowing through the cooling channel. The object is also achieved by a method, according to which a cooling side of the DC link device is fixed on a second cooling side opposite to the first cooling side of the cooling channel, so that waste heat from the DC link device can pass via the cooling side of the DC link device and via the second cooling side of the cooling channel into the coolant flowing through the cooling channel.

The DC link device is typically arranged as directly as possible on the one power module and is electrically conductively fixed thereon. According to the present disclosure, however, the thermal cooling and the discharge of the waste heat are the focus, which can arise both in the power module and in the DC link device; because the DC link device typically includes capacitors, dissipative waste heat arises due to the current load because of the power module. It is particularly advantageous to utilize the two cooling sides of the one cooling channel for this purpose, because according to this design no additional cooling structure has to be provided for the DC link device.

The power module contains power semiconductors in a quarter, half, or full bridge circuit, so that the converter, according to the present disclosure, is a modular element of a more comprehensive converter device, which can each have two, three, or more phases provided by the converter according to the present disclosure. The modular design of the converter according to the present disclosure enables the use of identical parts as components, so that the assembly assembled from the converters according to the present disclosure can both be adapted more easily to customer requirements and can be produced more cost-effectively, since the many identical components can be purchased more cost-effectively.

The assembly according to the present disclosure with converter, which is functional per se, can insofar be electrically and thermally conductively connected to other converters according to the present disclosure to form more complex converter devices.

To improve a heat transition from a cooling side into the coolant, according to one advantageous embodiment of the present disclosure, it can be provided that the cooling channel includes a heatsink introduced therein, wherein the first cooling side of the cooling channel includes at least one section of a first side of the heatsink and the heatsink is thermally operatively connected to both the power module and the coolant flowing through the cooling channel, so that the waste heat can pass better from the power module into the coolant. Optionally, it can be provided that the second cooling side of the cooling channel includes a second side, opposite to the first side, of the heatsink introduced into the cooling channel and the heatsink is thermally operatively connected to both the DC link device and the coolant flowing through the cooling channel, so that the waste heat can pass better from the DC link device into the coolant. In addition, it can be provided according to an advantageous embodiment of the method according to the present disclosure that a heatsink is introduced into the cooling channel before the at least two-part cooling channel is assembled and closed flow-tight.

The cooling channel comprises two component parts, wherein the first component part comprises the first cooling side of the cooling channel and the second component part comprises the second cooling side of the cooling channel. According to the present disclosure, the component part of the cooling channel comprising the first cooling side of the cooling channel is arranged and fixed on the power module. In a following step, the heatsink is inserted into this component part of the cooling channel, so that one side of the heatsink and the cooling side of the power module overlap and are thermally operatively connected. The second component part of the cooling channel is then fixed on the first component part of the cooling channel and both are connected to one another in a flow-tight manner, so that the coolant can flow through the cooling channel.

According to the present disclosure, the second component part of the cooling channel is designed such that the second cooling side of the cooling channel defined by the second component part is thermally operatively connected to the second side of the heatsink disposed in the cooling channel. In this case, the second component part of the cooling channel has a bulge or formation protruding into the cooling channel at the second side of the heatsink, wherein this formation exerts a pressure force on the second side of the heatsink and therefore the heatsink acts with the same pressure force against the power module. The component parts of the cooling channel can insofar advantageously be riveted or screwed together. A seal or a seal element can advantageously be arranged between the contact points of the component parts, so that the cooling channel is accordingly flow-tight for the coolant-which can be a liquid or air.

To improve the cooling effect of the one power module, it can be provided according to an advantageous embodiment of the present disclosure that the power module comprises a second cooling side opposite to the first cooling side, wherein the second cooling side of the power module is thermally operatively connected to a first cooling side of a second cooling channel, so that the waste heat from the power module can pass via the second cooling side of the power module and the first cooling side of the second cooling channel into a coolant flowing through the second cooling channel. Optionally, it can be provided according to the method according to the present disclosure that a second cooling channel is fixed with a first cooling side thereof disposed on a second cooling side of the power module, which is opposite to the first cooling side of the power module, so that the waste heat from the power module can pass via the second cooling side of the power module and the first cooling side of the second cooling channel into a coolant flowing through the second cooling channel.

The two-sided cooling of the power module advantageously results in improved discharge of the waste heat from the power module into the coolant of both the first cooling channel and the second cooling channel. Both cooling sides of the one power module are insofar thermally operatively connected to the power semiconductors of the power module, so that the waste heat generated in the power semiconductors can effectively be discharged via both cooling sides of the power module.

To be able to better utilize the cooling effect of the coolant, it can be provided according to one embodiment of the assembly with converter according to the present disclosure that the first and the second cooling channel have the same coolant. The coolant is first introduced here into one of the two cooling channels and discharged again via a return line through the other cooling channel. According to this embodiment, the coolant can absorb more waste heat from the power module, since the coolant has a longer dwell time on the cooling sides of the cooling channels and the power module and accordingly a larger amount of waste heat can pass into the coolant.

Alternatively to this through flow in series, a parallel through flow can also be advantageous in certain cases.

In order to be able to better utilize the second cooling channel, it can be provided according to an advantageous embodiment of the present disclosure that a cooling side of an electronics device is fixed on a second cooling side of the second cooling channel, which is opposite to the first cooling side of the second cooling channel. It can insofar be provided according to an optional embodiment of the method according to the present disclosure that an electronics unit is fixed with a cooling side thereof disposed on a second cooling side of the second cooling channel opposite to the first cooling side of the second cooling channel. It is known from practice that electronics devices for regulating and actuating the power module also generate a certain amount of waste heat, which is less than the amount of waste heat in the power module, but nonetheless damage to the electronics device can occur if the waste heat generated in the electronics device is not discharged.

In order that the waste heat can pass better from one cooling side into another cooling side, it can be provided according to one embodiment of the method according to the present disclosure that a heat conduction material is arranged between at least one cooling side pair of the cooling sides of the converter, and the heat conduction material is thermally operatively connected to the two paired cooling sides of the cooling side pair, so that the assembly with converter according to the present disclosure includes a heat conduction material arranged between at least one cooling side pair of the cooling sides fixed to one another, so that the two paired cooling sides of the cooling side pair are better thermally operatively connected. Heat conduction paste can be used as the conduction material, which is applied to the two thermally operatively connected cooling sides. Alternatively, one or more heat conduction pads can be used, by which a heat transition coefficient of the two cooling sides can be increased, so that the waste heat can pass better from one cooling side to the other. The thermal conduction material insofar fills up irregularities and small notches of the two cooling sides of the cooling side pair.

According to a particularly advantageous embodiment of the present disclosure, it can be provided that the converter is enclosed by a housing, wherein a housing inner wall exerts a perpendicular pressure force on the cooling sides. The pressure force exerted perpendicularly on the cooling sides according to this embodiment of the present disclosure improves the heat transition coefficient, since irregularities and notches in the cooling sides of the assembly with converter according to the present disclosure are smoothed out and pressed flat, so that the individual cooling side pairs have a larger thermally operatively connected and active contact surface. In addition, lower layer thicknesses of the heat conducting material or surface sealing material are required due to the higher contact pressure forces.

Since the assembly is independent and self-sufficient, it can also be placed in a relatively problem-free manner close to the parts to be actively cooled. Therefore, for example, the DC link capacitor can be actively cooled by suitable selection of the cooling channel materials and by using a heat conducting material or surface sealing material. If water flows around three half bridges on both sides, the further components can additionally also be cooled if the assembly is located between PCB and DC link.

The advantages are a more variable arrangement of the assembly, wherein a simpler possibility for active PCB cooling exists.

Further areas of applicability will become apparent from the description provided herein. The description and specific examples in this summary are intended for purposes of illustration only and are not intended to limit the scope of the present disclosure.

### BRIEF DESCRIPTION OF THE DRAWINGS

The drawings described herein are for illustrative purposes only of selected embodiments and not all possible implementations, and are not intended to limit the scope of the present disclosure.

FIG. 1 shows an assembly with converter having a power module and a DC link device as well as two cooling channels in a cross-sectional illustration and

FIG. 2 shows an assembly with converter having a power module and a DC link device as well as two cooling channels in an alternative arrangement of the components.

### DETAILED DESCRIPTION

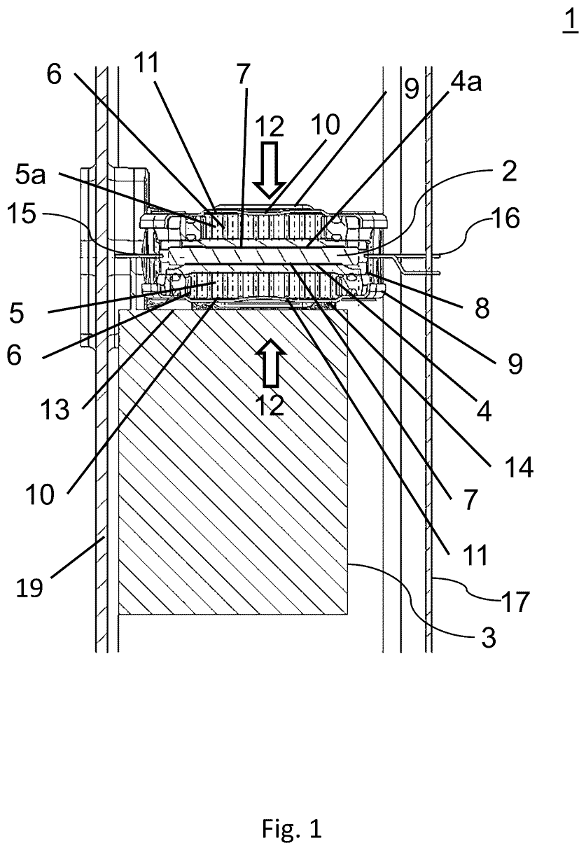

FIG. 1 shows an assembly 1 with converter in a cross-sectional illustration, which has a power module 2 and a DC link device 3. A cooling channel 5, 5a is arranged and fixed in each case on two opposite cooling sides 4, 4a—a first cooling side 4 and a second cooling side 4a—on the power module 2. A heatsink 6 is introduced into each of the cooling channels 5, 5a, which presses with a first cooling side 7 of the heatsink against the first cooling side 4 of the power module 2 and is thermally operatively connected thereto. Furthermore, the cooling channel 5, 5a includes a first component part 8 and a second component part 9, wherein the first component part 8 includes the first side 7 of the heatsink 6 for a heat transition of the waste heat from the power module 2 into a coolant flowing through the cooling channel 5.

The second component part 9 of the cooling channel 5, 5a is designed, bulged, and formed in such a way that an inner wall 10 of the cooling channel 5, 5a located at a second cooling side 11 of the heatsink 6 acts with a pressure force 12 against the second side 11 of the heatsink 5. If the component parts of the cooling channel 5, 5a are connected, sealed, and, for example, riveted together, the bulge of the second component part 9 of the two cooling channels 5, 5a acts with a pressure force 12 on both sides against the two heatsinks 6, so that the power module 2 is fixed in a friction-locked manner by the pressure force 12 acting on both sides on the power module 2. Advantageously and for reasons of cost, the first component part 8 consists of a plastic material and the second component part 9 consists of a metal or a spring steel, so that the pressure force 12 of the bulge of the second component part forming the cooling channel 5, 5a can be generated and exerted solely by a spring force of the spring steel.

The DC link device 3 is arranged and fixed with a cooling side 13 disposed against the second cooling side 11 of the first cooling channel 5 and is thermally operatively connected thereto via a heat conducting material or surface sealing material 14. In addition, the power module 2 is electrically conductively connected via DC power connections 15 to the DC link device 3, so that the power module 2 can convert a DC voltage in the DC link device 3 into a pulsed and cycled AC voltage. The power module 2 is insofar electrically conductively connected via AC power and actuation connections 16 to an electronics device 17.

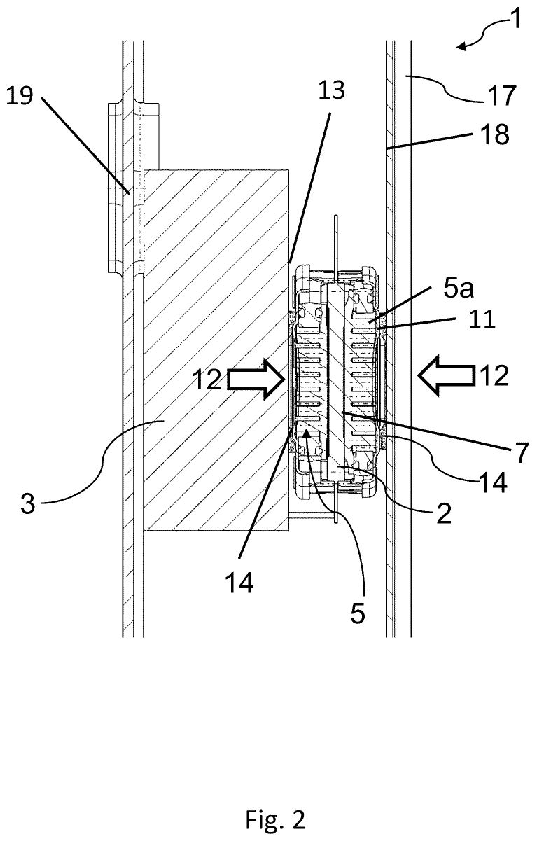

FIG. 2 shows, as in FIG. 1, an assembly 1 with converter, wherein the assembly 1 also comprises a power module 2, a DC link device 3, two cooling channels 5, 5a, and an electronics device 17. These components 2, 3, 5, 17 are arranged differently in comparison to FIG. 1 ; the power module 2 is now arranged rotated by 90° on the DC link device 3 in comparison to FIG. 1 and is fixed thereon. FIG. 2 shows that a cooling side 18 of the electronics device 17 is fixed on a second cooling side 11 of the second cooling channel 5a and the cooling side 18 of the electronics device 17 is thermally operatively connected via a further heat conducting material or surface sealing material 14 to the second cooling side 11 of the second cooling channel 5a. The power module 2 is therefore connected using the cooling channels 5, 5a on both sides on the two outer surfaces via the heat conducting materials or surface sealing materials to further electronic components.

The power module 2 and also the DC link device 3 as well as the electronics device 17 are all insofar cooled via the two cooling channels 5, 5a and the waste heat from these components of the converter is discharged by way of the coolant flowing in the cooling channels 5, 5a.

### LIST OF REFERENCE SIGNS (Part of the Description)

1 assembly
2 power module
3 DC link device
4, 4a cooling sides of the power module
5 cooling channel
6 heatsink
7 first cooling side of the heatsink/cooling channel
8 first component part of the cooling channel
9 second component part of the cooling channel
10 inner wall of the cooling channel
11 second side of the heatsink/cooling channel
12 pressure force
13 cooling side of the DC link device
14 heat conducting material or surface sealing material
15 DC line connections
16 AC power/actuation connections
17 electronics device
18 cooling side of the electronics device
19 housing

1. An assembly with converter for converting types of electric current and voltage, the assembly comprising:
a power module, which includes power semiconductors in a quarter, half, or full bridge circuit, and
a DC link device electrically conductively connected to the power module, wherein the DC link device includes capacitors and is electrically conductively connected to a power supply device, such that the converter converts one type of electric current or voltage into another, and
a cooling channel, wherein the cooling channel has a first cooling side and a second cooling side
wherein a first cooling side of the power module and the first cooling side of the cooling channel are fixed on one another and are thermally operatively connected to one another, such that waste heat passes from the power module, via the first cooling side of the power module and the first cooling side of the cooling channel, into coolant flowing through the cooling channel,
wherein a cooling side of the DC link device is fixed on the second cooling side of the cooling channel, wherein the second cooling side of the cooling channel is opposite to the power module, such that waste heat from the DC link device passes via the second cooling side of the cooling channel into the coolant flowing through the cooling channel,
wherein the cooling channel includes a first component part and a second component part,
wherein a heatsink having a first cooling side and a second cooling side is disposed within the cooling channel between the first component part and the second component part,
wherein the second component part of the cooling channel includes a bulge or formation, such that an inner wall of the second component part the cooling channel, at the second cooling side of a heatsink, acts with a pressure force against the second side of the heatsink.

2. The assembly with converter as claimed in claim 1, wherein, wherein the first cooling side of the cooling channel includes at least one section of first cooling side of the heatsink and the heatsink is thermally operatively connected to both the power module and to the coolant flowing through the cooling channel.

3. The assembly with converter as claimed in claim 2, wherein the second cooling side of the cooling channel includes the second cooling side of the heatsink, which is opposite to the first cooling side of the heatsink and the heatsink is thermally operatively connected both to the DC link device and to the coolant flowing through the cooling channel.

4. The assembly with converter as claimed in claim 1, wherein the cooling channel is a first cooling channel, wherein the power module includes a second cooling side of the power module opposite to the first cooling side of the power module, wherein the second cooling side of the power module is thermally operatively connected to a first cooling side of a second cooling channel, such that the waste heat from the power module passes via the second cooling side of the power module and the first cooling side of the second cooling channel into a coolant flowing through the second cooling channel.

5. The assembly with converter as claimed in claim 4, wherein parallel flow through both the first and second cooling channels with opposite inflow and outflow connecting pieces, or an asymmetrical volume distribution through both the first and second cooling channels with opposite inflow and outflow connecting pieces, or a through-flow in opposite directions with reversal and adjacent inflow and outflow connecting pieces takes place.

6. The assembly with converter as claimed in claim 4, wherein a cooling side of an electronics device is fixed on a second cooling side of the second cooling channel, which is opposite to the first cooling side of the second cooling channel.

7. The assembly with converter as claimed in claim 1, wherein a heat conducting material or surface sealing material is arranged between two cooling sides of at least one cooling side pair of the cooling sides of the converter, and the heat conducting material or surface sealing material is thermally operatively connected to the two cooling sides of the cooling side pair.

8. The assembly with converter as claimed in claim 1, wherein the converter is enclosed by a housing, wherein at least one housing inner wall exerts a perpendicular pressure force on the cooling sides of the power module of the heatsink.

9. A method for producing an assembly with converter, the method comprising:
fixing a power module having a first cooling side on a first cooling side of a cooling channel, wherein the cooling channel is formed in at least two pieces and is configured to have a coolant flow therethrough such that waste heat from the power module passes via the cooling sides of the power module and the cooling channel into the coolant flowing through the cooling channel, and
connecting a DC link device electrically conductively to the power module, such so that the converter converts one type of electric current or voltage into another,
fixing a cooling side of the DC link device on a second cooling side of the cooling channel, wherein the second cooling side of the cooling channel is opposite to the first cooling side of the cooling channel, such that waste heat from the DC link device passes via the cooling side of the DC link device and via the second cooling side of the cooling channel into the coolant flowing through the cooling channel.

10. The method as claimed in claim 9, wherein the cooling channel is an at least two-piece cooling channel, wherein a heatsink is introduced into the cooling channel before the at least two-piece cooling channel is assembled and closed flow-tight.

11. The method as claimed in claim 9, wherein the cooling channel is a first cooling channel, and a second cooling channel having a first cooling side is fixed on a second cooling side of the power module, wherein the second cooling side of the power module is opposite to the first cooling side of the power module, such that the waste heat from the power module passes via the second cooling side of the power module and the first cooling side of the second cooling channel into a coolant flowing through the second cooling channel.

12. The method as claimed in claim 11, wherein an electronics device having a cooling is fixed on a second cooling side of the second cooling channel, wherein the second cooling side of the second cooling channel is opposite to the first cooling side of the second cooling channel.

13. The method as claimed in claim 9, wherein a heat conducting material or surface sealing material is arranged between two cooling sides of at least one cooling side pair of the cooling sides fixed on one another, such so that the two cooling sides of the at least one cooling side pair are thermally operatively connected.

14. The method as claimed in claim 10, wherein the heatsink is pressed against the power module by a bulge or formation formed in a wall that defines the second cooling side of the cooling channel.

15. The assembly with converter of claim 1, wherein the cooling channel is a first cooling channel, wherein a second cooling channel is disposed on an opposite side of the power module, wherein the heatsink is a first heatsink disposed within the first cooling channel, and a second heatsink is disposed within the second cooling channel.

16. The assembly with converter of claim 15, wherein each of the first and second heatsinks are pressed against the power module by the bulge or formation of the second component part.

17. The assembly with converter of claim 15, wherein the first heatsink is thermally operative connected to both the power module and the DC link device, wherein the second heatsink is thermally operative connected to both the power module an electronics device disposed on the second heatsink on a side of the second heatsink opposite the power module.

18. The assembly with converter of claim 1, wherein the heatsink is thermally operatively connected to both the DC link device and the power module.

19. The assembly with converter of claim 15, wherein the first and second cooling channels are connected in series and share the same coolant, and the power module is cooled on both sides.

20. The assembly with converter of claim 15, wherein the first and second cooling channels are connected in parallel, and the power module is cooled on both sides.
